(19) United States
(12) Patent Application Publication
(10) Pub. No.: US 2012/0211269 A1
(43) Pub. Date: Aug. 23, 2012

(54) DEVICE MOUNTING BOARD AND METHOD OF MANUFACTURING THE SAME, SEMICONDUCTOR MODULE, AND MOBILE DEVICE

(75) Inventors: Kouichi SAITOU, Osaka (JP); Toshiya SHIMIZU, Osaka (JP)

(73) Assignee: SANYO ELECTRIC CO., LTD., Osaka (JP)

(21) Appl. No.: 13/460,403

(22) Filed: Apr. 30, 2012

Related U.S. Application Data
(63) Continuation of application No. PCT/JP2010/069349, filed on Oct. 29, 2010.

(30) Foreign Application Priority Data
Oct. 30, 2009 (JP) 2009-251205

(51) Int. Cl. H05K 1/18; B32B 38/10; H05K 1/02

(52) U.S. Cl. 174/260; 174/250; 156/219

(57) ABSTRACT

A device mounting board includes: an insulating resin layer; a wiring layer formed on one of the principal surfaces of the insulating resin layer; a protection layer covering the insulating resin layer and the wiring layer; a protruding electrode electrically connected to the wiring layer, the protruding electrode protruding from the wiring layer toward the insulating resin layer and penetrating through the insulating resin layer; a wiring-layer-side convex portion protruding from the wiring layer toward the insulating resin layer and having the top end thereof located inside the insulating resin layer; and a resin-layer-side convex portion protruding from the protection layer toward the insulating resin layer and having the top end thereof located inside the insulating resin layer.

### BACKGROUND OF THE INVENTION

1. Field of the Invention

The present invention relates to a device mounting board, a method of manufacturing the device mounting board, a semiconductor module, and a mobile device (portable device). More particularly, the present invention relates to a device mounting board on which semiconductor devices can be mounted by a flip-chip mounting technique, a method of manufacturing the device mounting board, a semiconductor module including the device mounting board, and the like.

2. Description of the Related Art

In recent years, there has been a demand for smaller semiconductor devices to be used in electronic apparatuses that have become smaller and more sophisticated. For example, a semiconductor package technique called CSP (Chip Size Package) has been rapidly becoming popular. By the CSP, a rewiring is formed over the electrodes on the chips and the solder bumps arranged in a lattice-like pattern on the package surface. Therefore, the layout is not limited by the device electrodes arranged at narrow pitch over the semiconductor pitch, and a semiconductor package having a size that is close to the size of a chip can be obtained.

Also, there is a known technique by which such a semiconductor device called the CSP is mounted on a wiring board by a technique called a face-down bonding technique. In view of such a technique, a semiconductor device has been developed, and in the semiconductor device, the characteristics of the sealing film are varied in the thickness direction thereof, so as to reduce the stress resulting from the thermal expansion coefficient difference between the silicon substrate and the sealing film.

### SUMMARY OF THE INVENTION

However, in the above mentioned semiconductor device, the sealing film is formed with different kinds of layers, which leads to complicated manufacturing procedures and higher costs. Also, the improved aspect in this structure is the junction between the semiconductor device and the wiring board, or particularly, the junction near the solder bumps. Therefore, there is still room for improvement in the adhesion between the wiring and the insulating film and the adhesion between the sealing film and the insulating film.

The present disclosure has been made in view of the above circumstances, and one non-limiting and exemplary embodiment provides a technique for improving the adhesion between different layers in a substrate on which semiconductor devices can be mounted. Additional benefits and advantages of the disclosed embodiments will be apparent from the specification and Figures. The benefits and/or advantages may be individually provided by the various embodiments and features of the specification and drawings disclosure, and need not all be provided in order to obtain one or more of the same.”

In one general aspect, the techniques disclosed here feature; a device mounting board comprising: a first insulating resin layer; a wiring layer formed on one of the principal surfaces of the first insulating resin layer; a second insulating resin layer covering the first insulating resin layer and the wiring layer; a protruding electrode electrically connected to the wiring layer, the protruding electrode protruding from the wiring layer toward the first insulating resin layer and penetrating through the first insulating resin layer; a wiring-layer-side convex portion protruding from the wiring layer toward the first insulating resin layer and having the top end thereof located inside the first insulating resin layer; and a resin-layer-side convex portion protruding from the second insulating resin layer toward the first insulating resin layer and having the top end thereof located inside the first insulating resin layer.

These general and specific aspects may be implemented using a system, a method, and a computer program, and any combination of systems, methods, and computer programs.

### BRIEF DESCRIPTION OF THE DRAWINGS

FIG. 1 is a schematic cross-sectional view of the structures of a device mounting board and a semiconductor module according to a first embodiment;

FIG. 2 is a diagram showing an optical photomicrograph of sub bumps formed on a copper plate as viewed from above;

FIG. 3 is a diagram showing a SEM photograph equivalent to a cross-sectional view taken along A-A of FIG. 2;

FIG. 4 is a diagram showing an optical photomicrograph of main bumps formed on a copper plate as viewed from above;

FIG. 5 is a diagram showing a SEM photograph equivalent to a cross-sectional view taken along B-B of FIG. 4;

FIGS. 6A through 6C are cross-sectional views illustrating procedures in a method of manufacturing the semiconductor module according to the first embodiment;

FIGS. 7A through 7C are cross-sectional views illustrating procedures in the method of manufacturing the semiconductor module according to the first embodiment;

FIGS. 8A through 8C are cross-sectional views illustrating procedures in the method of manufacturing the semiconductor module according to the first embodiment;

FIGS. 9A through 9C are cross-sectional views illustrating procedures in the method of manufacturing the semiconductor module according to the first embodiment;

FIGS. 10A through 10C are cross-sectional views illustrating procedures in the method of manufacturing the semiconductor module according to the first embodiment;

FIGS. 11A and 11B are cross-sectional views illustrating procedures in the method of manufacturing the semiconductor module according to the first embodiment;

FIGS. 12A and 12B are cross-sectional views illustrating procedures in the method of manufacturing the semiconductor module according to the first embodiment;

FIG. 13 is a cross-sectional view illustrating a procedure in a method of manufacturing a semiconductor module according to a second embodiment;

FIGS. 14A through 14C are cross-sectional views illustrating the procedures for processing a copperplate according to a third embodiment;

FIG. 15 is a cross-sectional view of a semiconductor module in which wiring-layer-side convex portions and resin-layer-side convex portions are formed by using sub bumps;

FIG. 16 is a diagram of the structure of a cell phone according to a fourth embodiment; and

FIG. 17 is a partial cross-sectional view of the cell phone shown in FIG. 16.

### DETAILED DESCRIPTION

The invention will now be described by reference to the preferred embodiments. This does not intend to limit the scope of the present disclosure, but to exemplify the invention.

To solve the above problems, a device mounting board as an aspect of the present disclosure includes: a first insulating resin layer; a wiring layer formed on one of the principal surfaces of the first insulating resin layer; a second insulating resin layer covering the first insulating resin layer and the wiring layer; a protruding electrode electrically connected to the wiring layer, the protruding electrode protruding from the wiring layer toward the first insulating resin layer and penetrating through the first insulating resin layer; a wiring-layer-side convex portion protruding from the wiring layer toward the first insulating resin layer and having the top end thereof located inside the first insulating resin layer; and a resin-layer-side convex portion protruding from the second insulating resin layer toward the first insulating resin layer and having the top end thereof located inside the first insulating resin layer.

According to this aspect, the adhesion between the wiring layer and the first insulating resin layer can be improved by the wiring-layer-side convex portion, and the adhesion between the first insulating resin layer and the second insulating resin layer can be improved by the resin-layer-side convex portion.

The wiring-layer-side convex portion may have a maximum height Rmax of 0.5 μm to 3.0 μm in surface roughness of the side surfaces thereof. Also, the wiring-layer-side convex portion may have a pole-like shape having a longitudinal direction intersecting with the longitudinal direction of the wiring layer. The wiring-layer-side convex portion may have a conical shape, a quadrangular pyramid shape, or a triangular pyramid shape. Here, a conical shape may not be a mathematically perfect cone, but may have an elliptical cross-sectional surface perpendicular to the stack direction. The gradient of the inclined surface of each convex portion may not be constant, as long as the size of the convex portion decreases toward the top end of the convex portion. For example, the wiring-layer-side convex portion may have an inclined surface gradient increasing toward the top end thereof. Also, the wiring-layer-side convex portion may have a height of 5 μm to 25 μm from the bottom portion of the surface of the wiring layer on the side facing the first insulating resin layer. The wiring-layer-side convex portion may include protrusions arranged in a predetermined pattern. The protrusions may have shapes similar to one another.

The resin-layer-side convex portion may have a conical shape, a quadrangular pyramid shape, or a triangular pyramid shape. Here, a conical shape may not be a mathematically perfect cone, but may have an elliptical cross-sectional surface perpendicular to the stack direction. The gradient of the inclined surface of each convex portion may not be constant, as long as the size of the convex portion decreases toward the top end of the convex portion. For example, the resin-layer-side convex portion may have an inclined surface gradient increasing toward the top end thereof. Also, the resin-layer-side convex portion may have a height of 5 to 25 μm from the bottom portion of the surface of the second insulating resin layer on the side facing the first insulating resin layer. The resin-layer-side convex portion may include protrusions arranged in a predetermined pattern. The protrusions may have shapes similar to one another.

Another aspect of the present disclosure is a semiconductor module. This semiconductor module includes the device mounting board and a semiconductor device having a device electrode joined to the protruding electrode of the device mounting board.

According to this aspect, the connection reliability between the device mounting board and the device electrode is increased in the semiconductor module.

Yet another aspect of the present disclosure is a mobile device. This mobile device includes the semiconductor module.

According to this aspect, connection reliability with another component via the device mounting board is increased in the mobile device, and in turn, the operation reliability of the mobile device is increased.

Still another aspect of the present disclosure is a method of manufacturing a device mounting board. This method is a method of manufacturing a device mounting board having an insulating resin layer and a wiring layer stacked therein. This method includes: forming a main bump for a protruding electrode on one of the principal surfaces of a metal plate for a wiring layer, and sub bumps that differ from the main bump; joining the one of the principal surfaces of the metal plate and a first insulating resin layer to each other, with top ends of the sub bumps being located inside the first insulating resin layer; removing a region from the metal plate, the region having part of the sub bumps formed therein; and stacking a second insulating resin layer to cover the first insulating resin layer having concave portions, after the sub bumps are partially removed in the removing.

According to this aspect, the adhesion between the wiring layer and the first insulating resin layer can be improved, and the adhesion between the first insulating resin layer and the second insulating resin layer can be improved, without any addition of an extra procedure.

In the bump forming procedure, the mask for forming the main bump and the mask for forming the sub bumps may be made to have different shapes from each other.

The following is a description of embodiments of the present disclosure, with reference to the accompanying drawings. In the drawings, like or similar components, members, and processes are denoted by like reference numerals, and the same explanation will not be given more than once. Also, the embodiments do not limit the invention but are merely examples, and all the features described in the following and combinations thereof are not necessarily the essence of the invention.

### First Embodiment

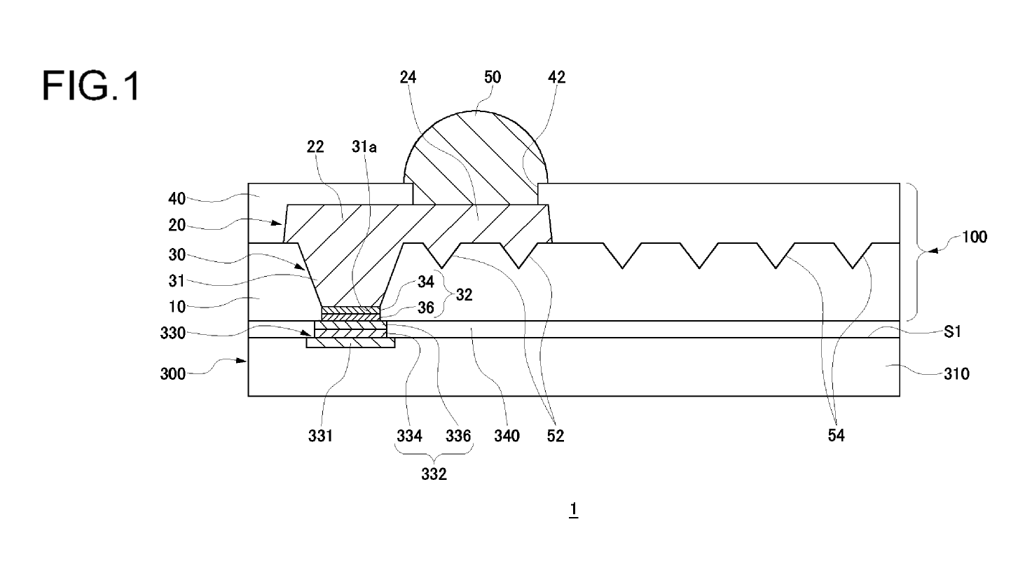

FIG. 1 is a schematic cross-sectional view of the structures of a device mounting board 100 and a semiconductor module 1 according to a first embodiment. The semiconductor module 1 has a structure in which a semiconductor device 300 is flip-chip connected to the device mounting board 100.

The semiconductor device 300 includes a semiconductor substrate 310, a device electrode 330, and a device protection layer 340.

The semiconductor substrate 310 is a P-type silicon wafer, for example. An integrated circuit (IC) or a large-scale integrated circuit (LSI) (not shown) is formed on the side of the principal surface S1 (the upper surface side in FIG. 1) of the semiconductor substrate 310 by a known technique.

A device electrode 330 connected to the integrated circuit is provided on the principal surface S1, which is the mounting surface. The device electrode 330 includes an electrode portion 331 and a metal layer 332 stacked on the surface of the electrode portion 331. The material of the electrode portion 331 is a metal such as aluminum (Al) or copper (Cu). The metal layer 332 includes a Ni layer 334 that is in contact with the electrode portion 331 and is made of nickel (Ni), and an Au layer 336 that is stacked on the Ni layer 334 and is made of gold (Au). That is, the metal layer 332 is a Ni/Au layer.

The device protection layer 340 is formed on the principal surface S1 of the semiconductor substrate 310 in such a manner as to expose the metal layer 332. A silicon oxide (SiO₂) film, a silicon nitride (SiN) film, a polyimide (PI) film, or the like is used as the device protection layer 340, for example.

The device mounting board 100 includes an insulting resin layer (a first insulating resin layer) 10, a wiring layer (a rewiring layer) 20 formed on one of the principal surfaces of the insulating resin layer 10, and a protruding electrode 30 that is electrically connected to the wiring layer 20 and protrudes from the wiring layer 20 toward the insulating resin layer 10.

The insulating resin layer 10 is made of an insulating resin, and serves as an adhesion layer between the wiring layer 20 and the semiconductor device 300. The insulating resin layer 10 may be a film-like adhesive resin called NCF (Non-Conductive Film) or an insulating material that causes plastic flow through pressure application.

An example of an insulating material that causes a plastic flow through pressure application is an epoxy thermosetting resin. The epoxy thermosetting resin used as the insulating resin layer 10 should be a material that has a viscosity of 1 kPa·s at a temperature 160° C. and a pressure of 8 MPa. Where a pressure of 5 to 15 MPa is applied to the epoxy thermosetting resin at a temperature of 160° C., for example, the resin viscosity decreases to approximately one eighth of the resin viscosity obtained where pressure is not applied. On the other hand, an epoxy resin in B stage prior to thermosetting neither has nor acquires viscosity at a temperature not higher than the glass transition temperature Tg, as in a case where pressure is not applied to the resin. The thickness of the insulating resin layer 10 is approximately 45 μm, for example.

The wiring layer 20 is formed on the principal surface on the opposite side of the insulating resin layer 10 from the semiconductor device 300, and is made of a conductive material or, for example, rolled metal, rolled copper. Rolled copper is higher in mechanical strength than a metal film that is made of copper and is formed by plating or the like. Rolled copper excels as a material for rewiring. The wiring layer 20 may be made of electrolytic copper or the like. The wiring layer 20 includes an electrode formation region 22 and a wiring region 24 continuing from the electrode formation region 22. The thickness of the wiring layer 20 is approximately 20 μm, for example.

In the electrode formation region 22, the protruding electrode 30 penetrating through the insulating resin layer 10 is formed in the position corresponding to the position of the device electrode 330 of the semiconductor device 300. In this embodiment, the wiring layer 20 and the protruding electrode 30 are integrally formed, so that the connection between the wiring layer 20 and the protruding electrode 30 is made secure. Also, since the wiring layer 20 and the protruding electrode 30 are integrally formed, formation of cracks and the like due to thermal stress generated in the usage environment of the semiconductor module 1 can be prevented in the interface between the wiring layer 20 and the protruding electrode 30. Further, the wiring layer 20 can be electrically connected to the device electrode 330 at the same time as the pressure bonding between the protruding electrode 30 and the device electrode 330. Accordingly, the number of procedures does not increase. In an end region of the wiring region 24, a land region that also serves as a wiring in which a later described solder ball 50 is provided is formed.

The protruding electrode 30 includes a protruding portion 31 integrally formed with the wiring layer 20, and a metal layer 32 stacked on the top surface 31a of the protruding portion 31. The protruding electrode 30 is designed to protrude from the wiring layer 20 toward the insulating resin layer 10 and penetrate through the insulating resin layer 10. The metal layer 32 includes a Ni layer 34 that is in contact with the protruding portion 31 and is made of nickel (Ni), and an Au layer 36 that is stacked on the Ni layer 34 and is made of gold (Au). That is, the metal layer 32 is a Ni/Au layer. The number of layers in the metal layer 32 is not particularly limited, as long as the metal layer 32 includes at least one layer.

In this embodiment, the metal layer 32 is stacked on the top surface 31a of the protruding portion 31 of the protruding electrode 30, and the metal layer 332 is stacked on the electrode portion 331 of the device electrode 330. As the metal layer 32 and the metal layer 332 form a Gold to Gold Interconnection (metal/metal junction), the protruding electrode 30 and the device electrode 330 are electrically connected to each other. Alternatively, the protruding electrode 30 and the device electrode 330 may be connected directly to each other. The diameter of the top end (the top surface) and the diameter of the base surface of the protruding electrode 30 are approximately 45 μmφ and 60 μmφ, respectively, for example. The heights of the protruding electrode 30 and the protruding portion 31 are approximately 25 μm and 20 μm, respectively, for example. The thicknesses of the Ni layer 34 and the Au layer 36 are approximately 1 μm to 15 μm and 0.03 μm to 1 μm, respectively, for example.

A protection layer (a second insulating resin layer) 40 for preventing oxidation of the wiring layer 20 or the like is formed on the principal surface on the opposite side of the wiring layer 20 from the insulating resin layer 10. The protection layer 40 may be a solder resist layer or the like. The protection layer 40 covers the insulating resin layer 10 and at least part of the wiring layer 20. An opening 42 is formed in a predetermined region of the protection layer 40, and the land region of the wiring layer 20 is exposed through the opening 42. In the opening 42, a solder ball 50 is formed as an external connection electrode, and the solder ball 50 and the wiring layer 20 are electrically connected. The position in which the solder ball 50 is formed, or the formation region of the opening 42 or the land region of the wiring layer 20, is the end portion of a routing by rewiring (the wiring layer 20), for example. The thickness of the protection layer 40 is approximately 30 μm, for example.

In the above description, the metal layer 32 formed with plating films is formed on the entire surface of the top surface 31a of the protruding portion 31 of the protruding electrode 30. However, the present disclosure is not limited to that. The metal layer 32 may be formed so as to cover the top surface 31a and the sidewalls of the protruding portion 31, or the metal layer 32 may be formed on part of the top surface 31a of the protruding portion 31.

### Improvement of Adhesion between Layers

As described above, the adhesion between the wiring layer 20 and the insulating resin layer 10, or the adhesion between the insulating resin layer 10 and the protection layer 40, affects the reliability of the device mounting board or the semiconductor module using the device mounting board. Therefore, in the device mounting board 100 according to this embodiment, concavities and convexities other than the protruding electrode 30 are formed in the region with which the respective layers are in contact. By virtue of those concavities and convexities, the adhesion between the respective layers is improved.

As the portions that form the concavities and convexities, the device mounting board 100 has wiring-layer-side convex portions 52 that are designed to protrude from the wiring layer 20 toward the insulating resin layer 10 and have top ends located inside the insulating resin layer 10, and resin-layer-side convex portions 54 that are designed to protrude from the protection layer 40 toward the insulating resin layer 10 and have top ends located inside the insulating resin layer 10 (see FIG. 1). The wiring-layer-side convex portions 52 and the resin-layer-side convex portions 54 are formed by using later described sub bumps. The sub bumps according to this embodiment are not bumps for electrodes, but include protrusions having shapes similar to the shapes of bumps for electrodes. Also, the sub bumps according to this embodiment are formed in the procedures for processing a copper plate for wiring.

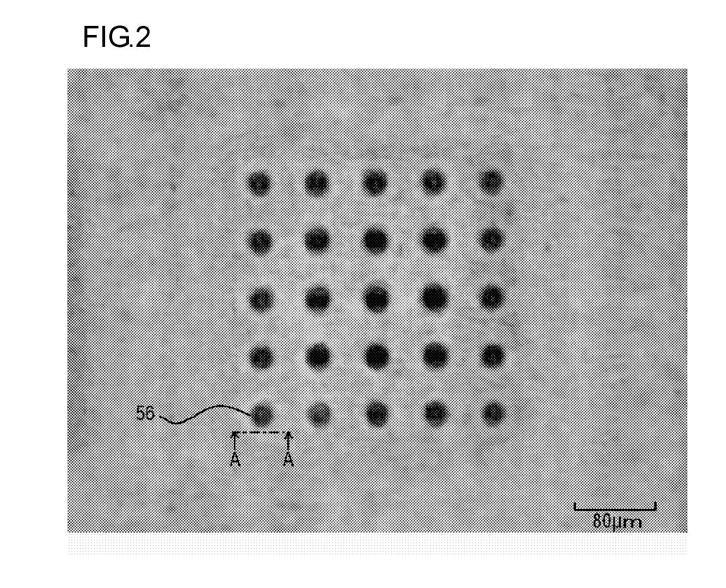

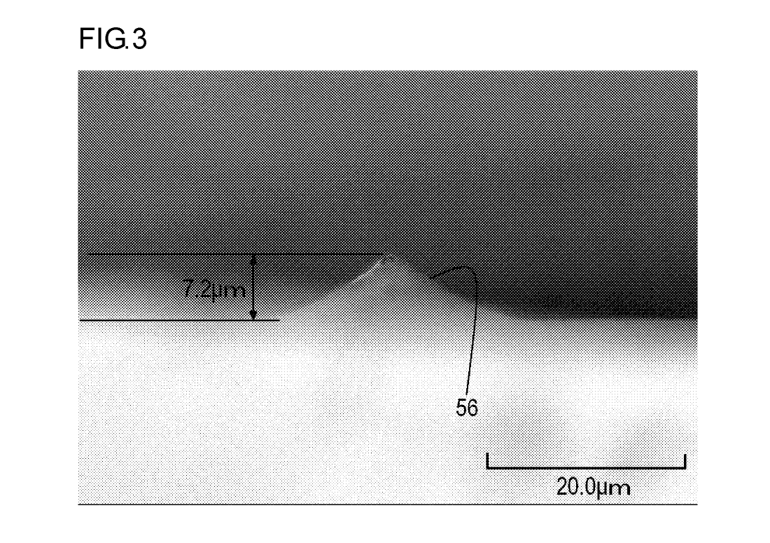

FIG. 2 shows an optical photomicrograph of sub bumps formed on a copper plate as viewed from above. FIG. 3 shows a SEM photograph equivalent to a cross-sectional view taken along A-A of FIG. 2. The sub bumps 56 form the wiring-layer-side convex portions 52 through the processing in a later procedure, and contribute to the formation of the resin-layer-side convex portions 54. The heights of the sub bumps 56 shown in FIGS. 2 and 3 were approximately 7.2 μm.

As shown in FIG. 2, the sub bumps 56 arranged in a matrix pattern are formed on one of the surfaces of a copper plate. The shapes of the sub bumps 56 are similar to one another. That is, the sub bumps 56 arranged in a predetermined pattern can be formed by artificially determining the size and layout of the mask (a resist pattern) used in the etching of the copper plate in the later described manufacturing process. The sub bumps 56 in the photograph in FIG. 2 are generally shown as dark circular shapes, which mean that there are no flat surfaces when viewed from above. In other words, the top ends of the sub bumps 56 are sharp, and have substantially conical shapes. Also, as shown in FIG. 3, the gradient of the inclined surface of each of the sub bumps 56 increases toward the top end. The curvature of each of the sub bumps 56 is low and changes gradually in the bottom portions of the side surfaces thereof. Since the sub bumps 56 have substantially conical shapes as described above, the resistance is low when the sub bumps 56 enter the insulating resin layer 10 so as to connect the wiring layer 20 and the insulating resin layer 10. The shapes of the sub bumps 56 are not limited to conical shapes.

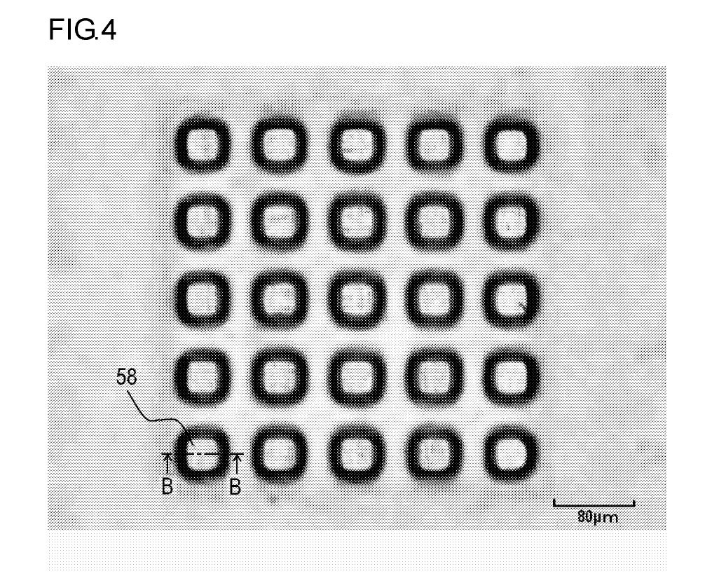

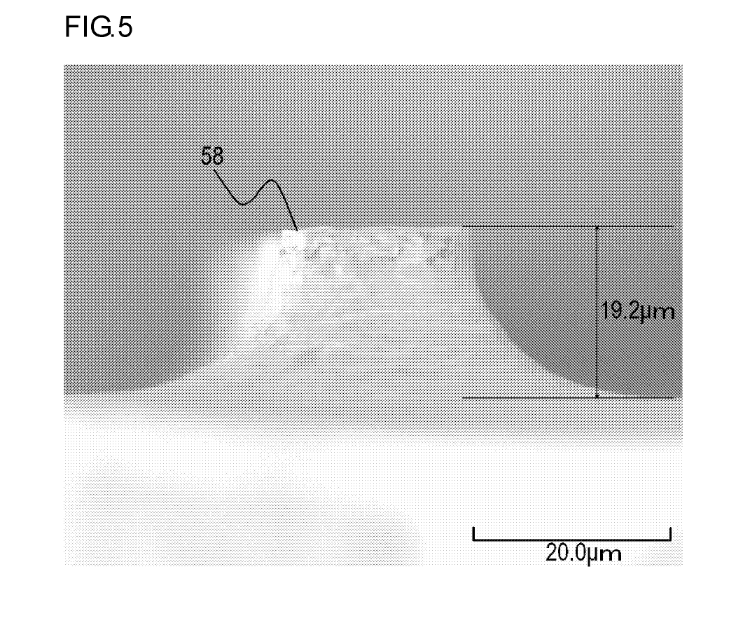

FIG. 4 shows an optical photomicrograph of main bumps formed on a copper plate as viewed from above. FIG. 5 shows a SEM photograph equivalent to a cross-sectional view taken along B-B of FIG. 4. The heights of the main bumps 58 shown in FIGS. 4 and 5 are approximately 19.2 μm.

As shown in FIG. 4, the main bumps 58 arranged in a matrix pattern are formed on one of the surfaces of a copper plate. The main bumps 58 greatly differ from the sub bumps 56 of FIG. 2 in that the top ends have flat surfaces and trapezoidal shapes. The shapes of the main bumps 58 are similar to one another. The heights and shapes of the main bumps can be changed by adjusting the moving speed of the copperplate in the wet etching procedure, for example.

By using the sub bumps formed in the above manner as the wiring-layer-side convex portions 52, large concavities and convexities that are not formed by a conventional surface roughening process can be formed in the boundary between the insulating resin layer 10 and the wiring layer 20. As a result, the adhesion between the insulating resin layer 10 and the wiring layer 20 that are different layers existing inside the device mounting board 100 is improved, and the reliability of the device mounting board 100 is increased. Also, as will be described in the later explanation of the manufacturing method, the adhesion between the insulating resin layer 10 and the protection layer 40 is also improved and the reliability of the device mounting board 100 is increased by the resin-layer-side convex portions 54 that are formed in the interface between the insulating resin layer 10 and the protection layer 40, and have the same shapes and effects as those of the wiring-layer-side convex portions 52.

### Method of Manufacturing Mounting board and Semiconductor Module

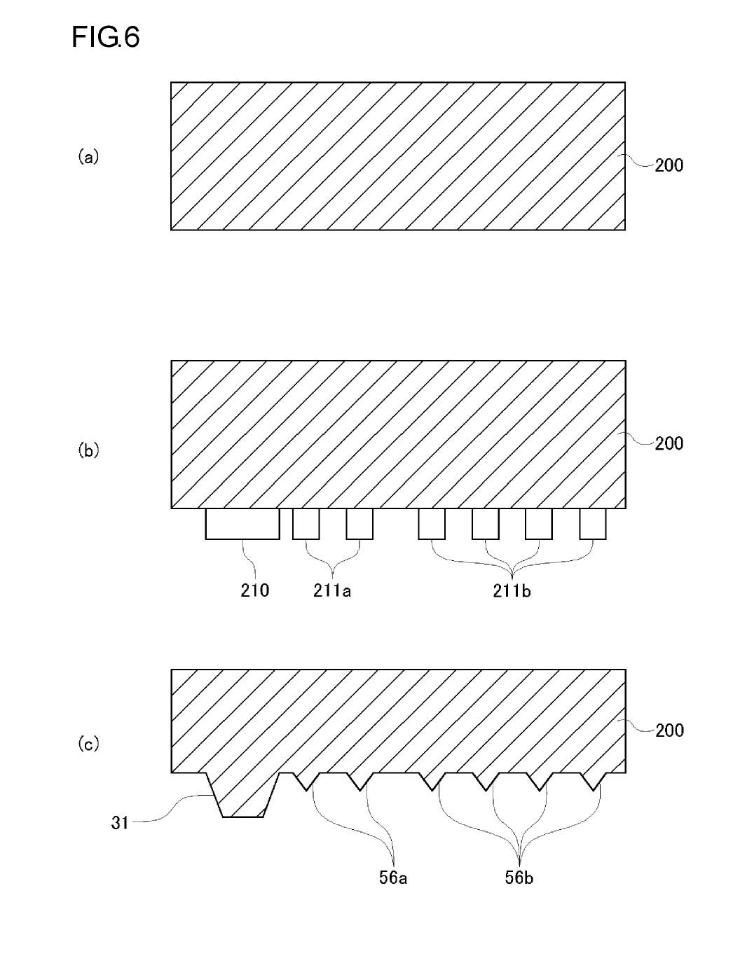

Referring to FIGS. 6A through 12B, a method of manufacturing the semiconductor module according to the first embodiment is described. FIGS. 6A through 12B are cross-sectional views illustrating the procedures for manufacturing the semiconductor module according to the first embodiment.

First, as shown in FIG. 6A, a copper plate 200 is prepared as a metal plate having a greater thickness at least than the sum of the height of the protruding portion 31 of the protruding electrode 30 and the thickness of the wiring layer 20 shown in FIG. 1. A rolled metal plate made of rolled copper is used as the copper plate 200.

As shown in FIG. 6B, a resist 210 is selectively formed on one of the principal surfaces of the copper plate 200 by a photolithography technique, in accordance with a pattern corresponding to the region in which the protruding electrode 30 is to be formed. At this point, resists 211a and 211b are also selectively formed in accordance with a pattern corresponding to the regions in which the above described sub bumps 56 are to be formed. The resists 211a correspond to sub bumps 56a (described later) forming the wiring-layer-side convex portions 52 among the sub bumps 56, and the resists 211b correspond to sub bumps 56b (described later) contributing to the formation of the resin-layer-side convex portions 54 among the sub bumps 56. The resists 211a and 211b are designed to have shapes and sizes in accordance with desired shapes and sizes of the wiring-layer-side convex portions 52 and the resin-layer-side convex portions 54. Also, the resists 211a may have different sizes and shapes from those of the resists 211b.

The layout of the formation region of the protruding electrode 30 corresponds to the position of each device electrode 330 (see FIG. 1) of the semiconductor substrate 310 divided into semiconductor module formation regions by scribe lines (lines for dividing the semiconductor substrate 310 by scribing in a later stage). Specifically, a resist film of a predetermined film thickness is bonded to the copperplate 200 with a laminator device, and exposure is performed with the use of a photomask having a pattern of the protruding electrode 30 and the sub bumps 56a and 56b (hereinafter referred to as the “sub bumps 56”, where appropriate), followed by development. In this manner, the resists 210, 211a, and 211b (hereinafter referred to as the “resists 211”, where appropriate) are selectively formed on the copperplate 200. To improve the adhesion to the resists, for example, preprocessing such as polishing and cleaning of the surface of the copperplate 200 is performed as needed, prior to the lamination of the resist films.

As shown in FIG. 6C, with the resists 210 and 211 serving as masks, a wet etching process using a chemical solution such as aqueous ferric chloride is performed. In this manner, the protruding portion 31 and the sub bumps 56 that protrude from the surface of the copper plate 200 and have a predetermined pattern of truncated cones are formed under the same conditions at the same time. At this point, the shapes and sizes of the protruding portion 31 and the sub bumps 56 are the same as those of the above described main bumps 58 and the sub bumps 56. After the protruding portion 31 and the sub bumps 56 are formed, the resists 210 and 211 are removed with a release agent. Here, the protruding portion 31 is equivalent to each of the above described main bumps 58, and the shape and the like of the protruding portion 31 are as described above.

Through the above described procedures, the protruding portion 31 as the main bump for the protruding electrode, and the sub bumps 56 are simultaneously and integrally formed on one of the principal surfaces of the copperplate 200 for the wiring layer. Instead of the resist 210, a metal mask such as a silver (Ag) mask may be used. In that case, a sufficient etching selection ratio with respect to the copper plate 200 is secured, and accordingly, finer patterning of the protruding electrode 30 can be performed.

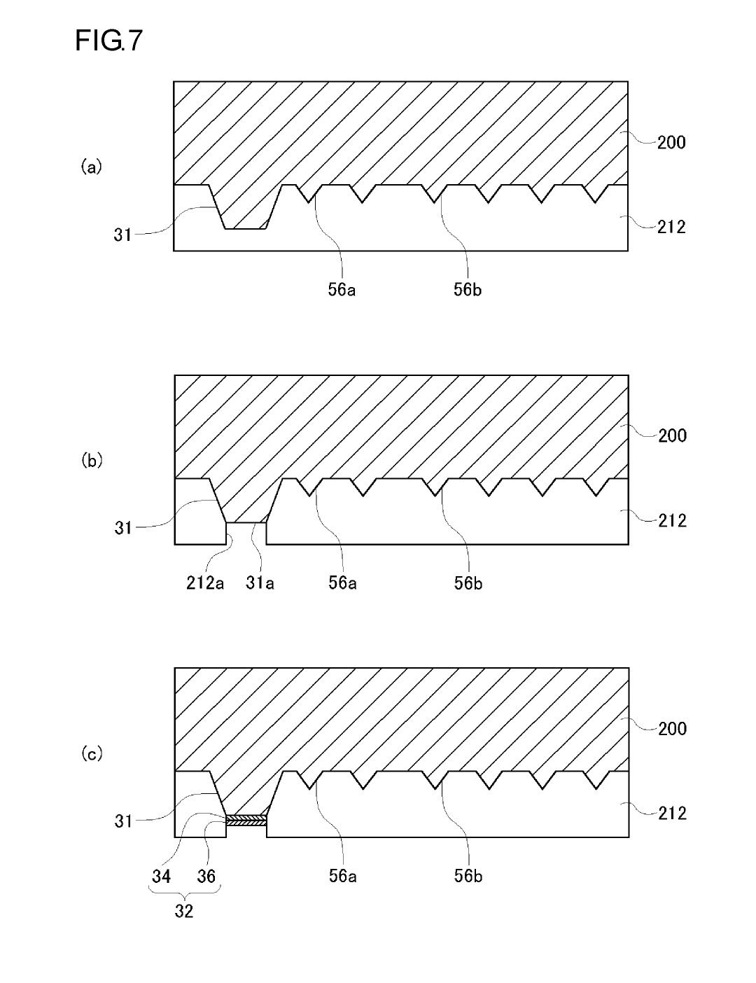

As shown in FIG. 7A, the resists 212 having resistance to plating are stacked on the principal surface of the copperplate 200 having the protruding portion 31 formed thereon, so that the protruding portion 31 is buried. It should be noted that, to protect the copper plate 200, for example, a resist protection film (not shown) is formed on the entire surface on the opposite side (the upper surface side) from the surface having the resist 210 formed thereon.

As shown in FIG. 7B, an opening 212a is formed by a lithography technique, to expose the top surface 31a of the protruding portion 31.

As shown in FIG. 7C, with the resists 212 serving as masks, the Ni layer 34 is formed as a metal layer by an electrolytic plating technique, for example, on the top surface 31a exposed through the opening 212a. With the resists 212 serving as masks, the Au layer 36 is then formed as a metal layer by an electrolytic plating technique, for example, on the surface of the Ni layer 34 exposed through the opening 212a.

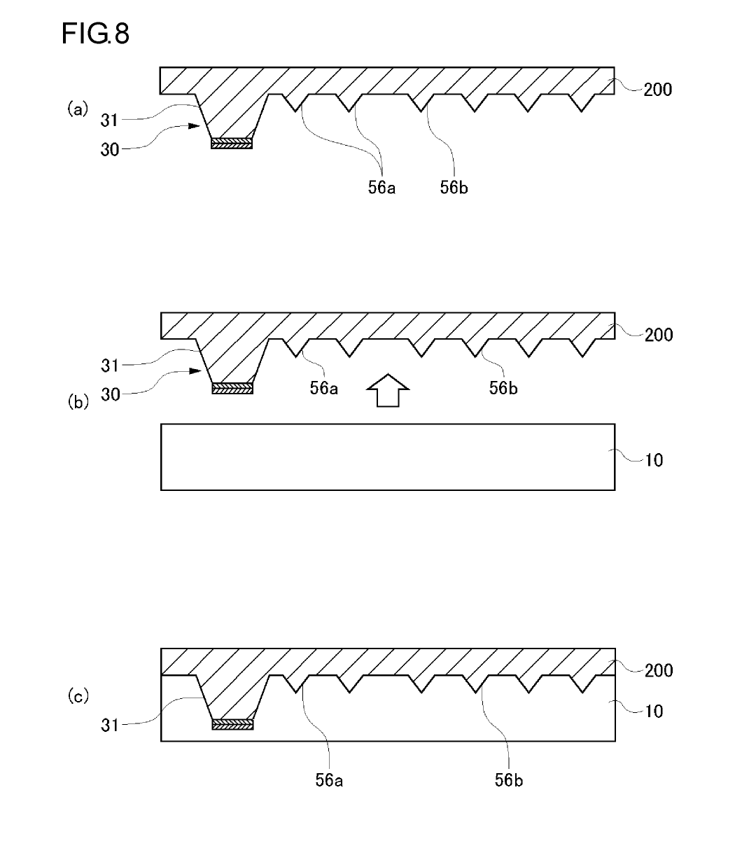

As shown in FIG. 8A, the resists 212 are then removed with a release agent. Through the above described procedures, the protruding electrode 30 and the sub bumps 56 are integrally formed on the copper plate 200. If necessary, etchback is performed on the surface of the copper plate 200 on the opposite side from the side having the protruding electrode 30 formed thereon, by a wet etching process or the like using a chemical solution such as aqueous ferric chloride. In this manner, the copperplate 200 is made thinner. At this point, a resist protection film (not shown) is formed on the principal surface of the copper plate 200 on the side having the protruding electrode 30 formed thereon, so that the protruding electrode 30, the sub bumps 56, and the copper plate 200 are protected. After an etching process, the resist protection film is removed. In this manner, the thickness of the copper plate 200 can be adjusted to a predetermined thickness (the thickness of the wiring layer 20).

After that, for example, a roughening process is performed on one of the surfaces of the copper plate 200 having the protruding portion 31 and the sub bumps 56 formed thereon. As the roughening process, chemical processing such as CZ processing (a registered trade name), or plasma processing may be performed, for example. In the CZ processing, the copper plate 200 is immersed into a chemical solution that is a mixed solution of formic acid and hydrochloric acid, for example, and etching is performed on the surfaces of the protruding electrode 30 and the sub bumps 56. In this manner, the surfaces of the protruding electrode 30 and the sub bumps 56 are roughened.

Since the copper plate 200 is made of rolled copper in this embodiment, the crystal grains of the copper forming the protruding electrode 30 and the sub bumps 56 are aligned so that the long axis extends parallel to the top surface of the protruding electrode 30, and the short axis extends substantially perpendicular to the top surface of the protruding electrode 30. Therefore, by roughening the surfaces of the protruding electrode 30 and the sub bumps 56, the concavities and convexities in accordance with the crystal grains of the copper are formed on the side surfaces of the protruding electrode 30 and the sub bumps 56, and the top surface of the protruding electrode 30 can be maintained substantially in a horizontal position. In the case of plasma processing, the copper plate 200 is exposed to a plasma gas atmosphere containing 40 sccm of oxygen and 60 sccm of chlorine at a high-frequency output of 600 W and a pressure of 1.5 Pa, for example, for a predetermined period of time. Etching is then performed on the surface of the protruding electrode 30 and the sub bumps 56, to roughen the surfaces of the protruding electrode 30 and the sub bumps 56. In the case of plasma processing, the top surface of the protruding electrode 30 is covered, so as not to be roughened.

At this point, the surface roughness of the side surfaces of the protruding electrode 30 and the sub bumps 56 has a maximum height Rmax in the range of 0.5 μm to 3.0 μm. If the maximum height Rmax of the surface roughness of the side surfaces is smaller than 0.5 μm, the desired anchor effect to improve the adhesion between the protruding electrode 30 and the insulating resin layer 10 and the adhesion between the sub bumps 56 and the insulating resin layer 10 is not easily achieved. If the maximum height Rmax is larger than 3.0 μm, the insulating resin layer 10 cannot enter the concave portions, and there is a possibility that a space is formed between the protruding electrode 30 and the insulating resin layer 10 and between the sub bumps 56 and the insulating resin layer 10. As the spaces become larger, the protruding electrode 30 and the sub bumps 56 are easily detached from the insulating resin layer 10 due to the spaces when thermal stress is applied. Therefore, the sizes of the concavities and convexities fall within the above range, for example. The sizes of concavities and convexities that can achieve the desired anchor effect can be determined through an experiment. For example, the maximum height Rmax of the surface roughness of the side surfaces of the protruding electrode 30 and the sub bumps 56 is in the range of 1.0 μm to 2.0 μm.

As shown in FIG. 8B, the insulating resin layer 10 is stacked on the surface of the copper plate 200 on the side having the protruding electrode 30 formed thereon. Specifically, one of the principal surfaces of the copper plate 200 and the insulating resin layer 10 are joined to each other, so that the top ends of the sub bumps 56 are located inside the insulating resin layer 10. The insulating resin layer 10 according to this embodiment is a film-like epoxy-based connecting material having bonding and insulating functions. In an uncured state, this material has excellent thermal flow properties, mechanical properties, surface adherence properties, and optical properties. This material also has a relatively low linear expansion coefficient and excellent adhesive properties after curing, which leads to a high connection reliability. Specifically, the insulating resin layer 10 in a resin uncured state has a high fluidity to realize excellent bump embedment in the laminating procedure (at approximately 80° C.), and has mechanical properties to endure the cutting in the later described dicing procedure (at room temperature).

The insulating resin layer 10 having the above described structure is stacked on the copper plate 200, and the protruding portion 31 and the sub bumps 56 of the copper plate 200 are readily buried in the insulating resin layer 10 (see FIG. 8C).

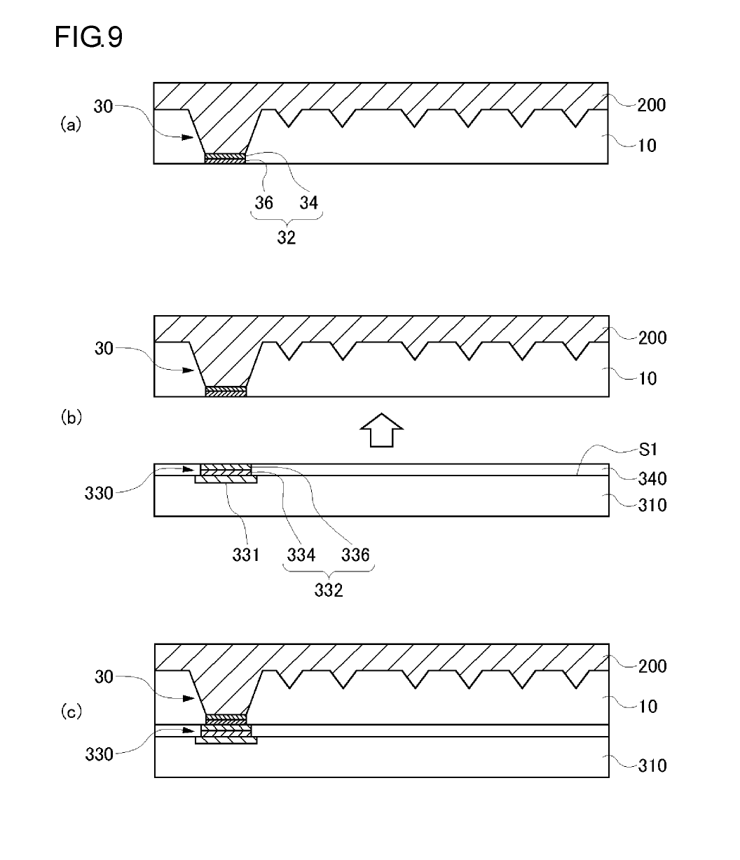

As shown in FIG. 9A, by using O₂ plasma etching or the like, the insulating resin layer 10 is made thinner so as to expose the metal layer 32 formed on the top surface of the protruding electrode 30. In this embodiment, the Au layer 36 is exposed as the surface of the metal layer 32.

As shown in FIG. 9B, the semiconductor substrate 310 (a 6-inch semiconductor wafer) having semiconductor module formation regions that include device electrodes 330 and device protection layers 340 and are defined by scribe lines on the principal surface S1 is prepared. The drawing shows the essential components of one semiconductor module as part of the semiconductor substrate 310. Specifically, in each semiconductor module formation region in the semiconductor substrate 310 such as a P-type silicon substrate, a predetermined integrated circuit is formed, and the electrode portion 331 of the device electrode 330 is formed on the external peripheral portion of the integrated circuit by performing a semiconductor manufacturing process combining a known lithography technique, a known etching technique, a known ion injection technique, a known film formation technique, a known heat treatment technique, and the like. The device protection layer 340 with insulating properties is then formed on the area of the principal surface S1 of the semiconductor substrate 310 other than the electrode portion 331, and the metal layer 332 formed with the Ni layer 334 and the Au layer 336 is stacked on the electrode portion 331, to form the device electrode 330.

As shown in FIG. 9B, the copper plate 200 having the insulating resin layer 10 stacked thereon and the semiconductor substrate 310 are positioned so that the protruding electrode 30 and the device electrode 330 face each other. The copper plate 200 and the semiconductor substrate 310 are then pressure-bonded to each other by a pressing device. In this manner, the copper plate 200, the insulating resin layer 10, and the semiconductor substrate 310 are integrated as shown in FIG. 9C. The protruding electrode 30 and the device electrode 330 are pressure-bonded to each other, and the protruding electrode 30 and the device electrode 330 are electrically connected to each other.

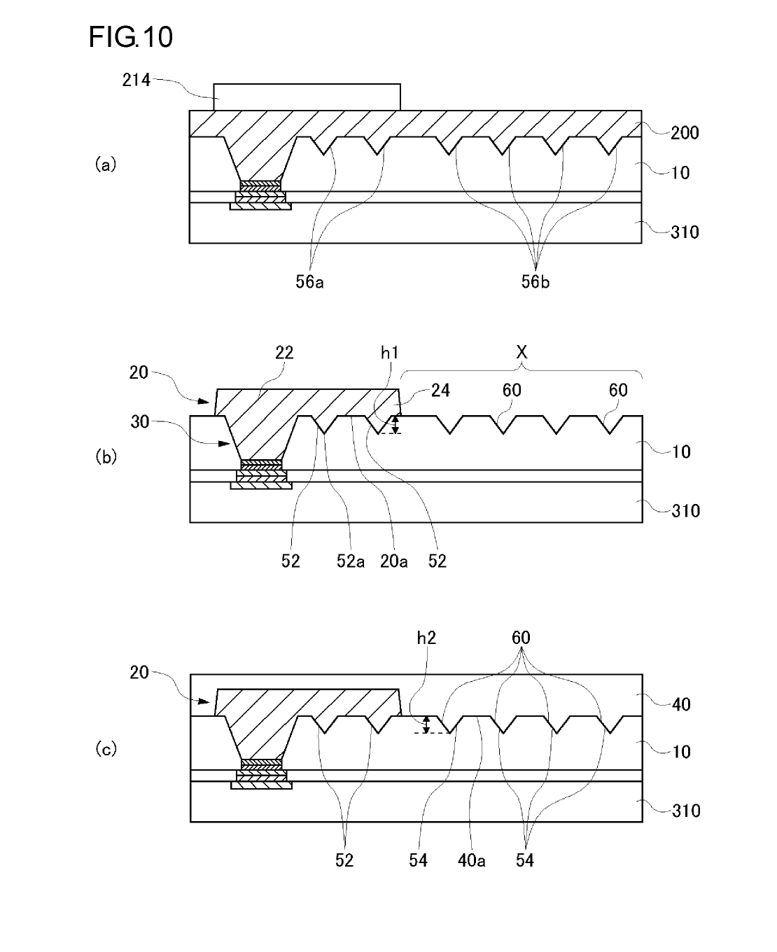

As shown in FIG. 10A, a resist 214 having a pattern corresponding to the region in which the wiring layer 20 is to be formed is selectively formed on the surface of the copperplate 200 on the opposite side from the insulating resin layer 10 by using a photolithography technique.

As shown in FIG. 10B, with the resist 214 serving as a mask, the copper plate 200 is processed into a predetermined pattern by using an etching technique, to form the wiring layer 20 (the rewiring). In this embodiment, the region X in which the sub bumps 56b of the sub bumps 56 are formed are removed from the copperplate 200 at this point. Concave portions 60 having conical shapes corresponding to the shapes of the sub bumps 56b are formed on the surface of the insulating resin film 10 from which the sub bumps 56b have been removed. The surface forms of the sub bumps 56b subjected to the roughening process are transferred onto the surfaces of the concave portions 60. The wiring layer 20 formed in this manner includes the electrode formation region 22 in which the protruding electrode 30 is formed, the wiring region 24 continuing from the electrode formation region 22, and the wiring-layer-side convex portions 52 protruding from the wiring region 24 toward the insulating resin layer 10. The wiring-layer-side convex portions 52 are designed so that the top ends 52a thereof are located inside the insulating resin layer 10.

Since the sub bumps 56a are used as the wiring-layer-side convex portions 52, the maximum height Rmax of the surface roughness of the side surfaces is in the range of 0.5 μm to 3.0 μm. The wiring-layer-side convex portions 52 can also be regarded as protrusions arranged in a predetermined pattern, and have shapes similar to one another. The wiring-layer-side convex portions 52 are designed so that the height h1 from the bottom portion 20a of the surface of the wiring layer 20 on the side facing the insulating resin layer 10 is in the range of 5 μm to 25 μm. The numerical value range can be calculated through an experiment or a calculation in accordance with the thicknesses and materials of the respective layers in the substrate. After the wiring layer 20 is formed, the resist 214 is removed.

As shown in FIG. 10C, the protection layer (a photo solder resist layer) 40 is stacked on the wiring layer 20 and the insulating resin layer 10. At this point, the protection layer 40 covers the insulating resin layer 10 so as to fill the concave portions 60. As a result, the resin-layer-side convex portions 54 that protrude from the protection layer 40 toward the insulating resin layer 10 and have the top ends located inside the insulating resin layer 10 are formed. As the concave portions 60 formed by removing the sub bumps 56b are filled with the protection layer 40, the side surfaces of the resin-layer-side convex portions 54 have the same roughness as that of the side surfaces of the sub bumps 56b.

The resin-layer-side convex portions 54 have the same conical shapes as those of the sub bumps 56b or the wiring-layer-side convex portions 52. Accordingly, the shapes of the resin-layer-side convex portions 54 are the same as those of the wiring-layer-side convex portions 52. The shapes of resin-layer-side convex portions 54 are similar to one another. In the resin-layer-side convex portions 54, the height h2 from the bottom portion 40a of the surface of the protection layer 40 on the side facing the insulating resin layer 10 may be 5 μm to 25 μm. Also, the resin-layer-side convex portions 54 according to this embodiment are arranged in a predetermined pattern.

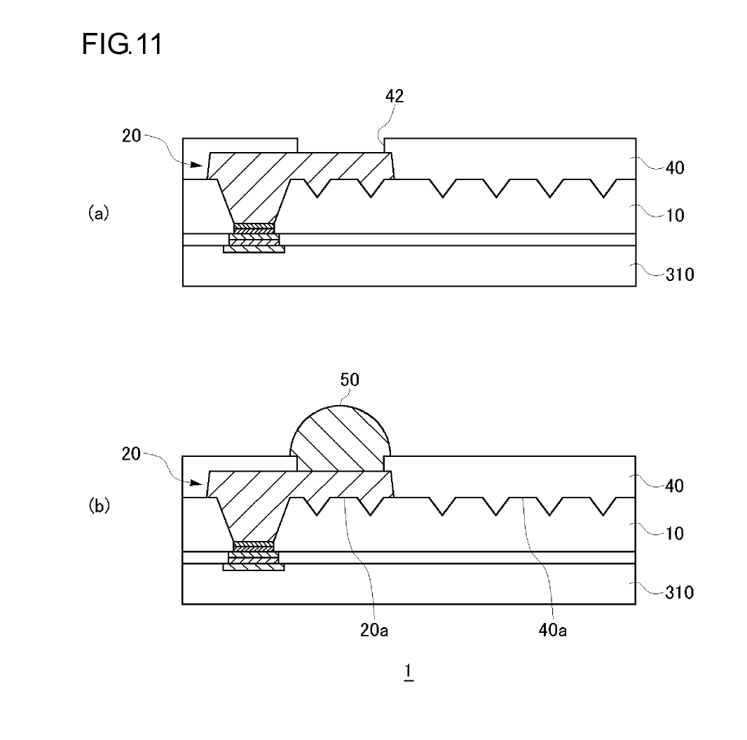

As shown in FIG. 11A, the opening 42 is formed in a predetermined region (a solder ball mounting region) of the protection layer 40 by a photolithography technique.

As shown in FIG. 11B, the solder ball 50 is mounted in the opening 42 of the protection layer 40 by a screen printing technique. Specifically, a solder paste formed by turning a resin and a solder material into a paste-like state is printed on a desired region with a screen mask, and is heated to the solder melting temperature, to form the solder ball 50. In this manner, the semiconductor module 1 is completed.

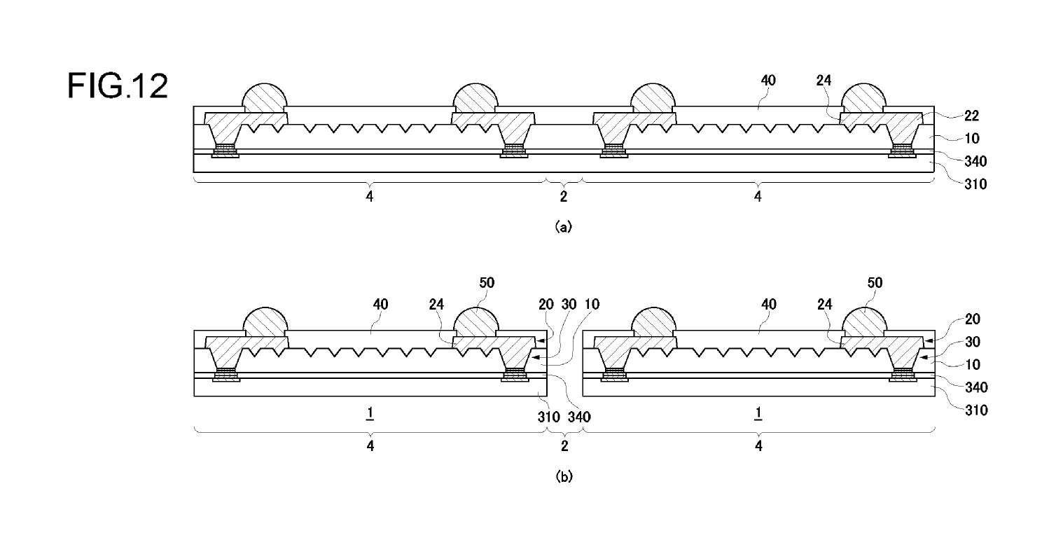

Although each of the above described drawings shows part of the semiconductor module for ease of explanation, the semiconductor substrate 310 is designed to have semiconductor modules arranged as shown in FIG. 12A in practice.

As shown in FIG. 12B, dicing is performed on the back surface (the lower surface side) of the semiconductor substrate 310, along the scribe lines 2 defining the semiconductor module formation regions 4. In this manner, semiconductor modules 1 are separated from one another. After that, cleaning is performed on the individual semiconductor modules 1 with a chemical solution, to remove residues and the like formed at the time of dicing. Through the above described procedures, the semiconductor modules 1 can be manufactured. In a case where the semiconductor substrate 310 (the semiconductor device 300) is not mounted, the device mounting board 100 can be obtained.

To sum up the functions and effects of the above described structure, the device mounting board 100 according to the first embodiment includes the wiring-layer-side convex portions 52 that are designed to protrude from the wiring layer 20 toward the insulating resin layer 10 and have the top ends thereof located inside the insulating resin layer 10. Accordingly, the boundary surface between the insulating resin layer 10 and the wiring layer 20 has large concavities and convexities, and the adhesion is improved. As the roughening process is performed on the side surfaces of the wiring-layer-side convex portions 52 in the stage of the sub bumps 56a, the adhesion between the wiring-layer-side convex portions 52 and the insulating resin layer 10, and the adhesion between the wiring layer 20 and the insulating resin layer 10 are further improved.

In addition to that, the device mounting board 100 includes the resin-layer-side convex portions 54 that are designed to protrude from the protection layer 40 toward the insulating resin layer 10 and have the top ends thereof located inside the insulating resin layer 10. Accordingly, the boundary surface between the protection layer 40 and the insulating resin layer 10 has large concavities and convexities, and the adhesion is improved. As the resin-layer-side convex portions 54 are formed by filling the concave portions 60 from which the sub bumps 56b have been removed with the protection layer 40, the resin-layer-side convex portions 54 have the same surface forms as those of the roughened sub bumps 56b. As a result, the adhesion between the resin-layer-side convex portions 54 and the insulating resin layer 10, and the adhesion between the protection layer 40 and the insulating resin layer 10 are further improved.

By the method of manufacturing the device mounting board according to this embodiment, the sizes of the resists 210 and 211 are set in the procedure illustrated in FIG. 6A, so that the sub bumps 56 for forming the wiring-layer-side convex portions 52 and the resin-layer-side convex portions 54 can be formed at the same time as the formation of the protruding portion 31 of the protruding electrode 30. Also, in the procedure illustrated in FIG. 10C, the resin-layer-side convex portions 54 are formed at the same time as the covering of the insulating resin layer 10 with the protection layer 40. That is, by the manufacturing method according to this embodiment, there is no need to add any new step to the conventional manufacturing process, and the device mounting board 100 including the wiring-layer-side convex portions 52 and the resin-layer-side convex portions 54 can be easily manufactured.

As shown in FIG. 11B, the wiring-layer-side convex portions 52 and the resin-layer-side convex portions 54 according to this embodiment protrude and have sharp top ends unlike the bottom portions 20a and 40a that are flat surfaces of the wiring layer 20 and the protection layer 40. However, the wiring-layer-side convex portions 52 and the resin-layer-side convex portions 54 are not limited to the above. For example, the top ends of the wiring-layer-side convex portions and the resin-layer-side convex portions may have flat surfaces.

### Second Embodiment

In the above described first embodiment, after the copper plate 200 and the insulating resin layer 10 are adhered to each other, the copper plate 200 and the semiconductor substrate 310 are pressure-bonded to each other via the insulating resin layer 10, to form the semiconductor module 1. However, the semiconductor module 1 may be formed in the following manner. A second embodiment is now described. The fundamental structure of the semiconductor module 1 and the procedures for manufacturing the protruding electrode 30 are basically the same as those of the first embodiment. Therefore, the same components as those of the first embodiments are denoted by the same reference numerals as those used in the first embodiment, and explanation thereof will be omitted where appropriate. The aspects that differ from the first embodiment are now mainly described.

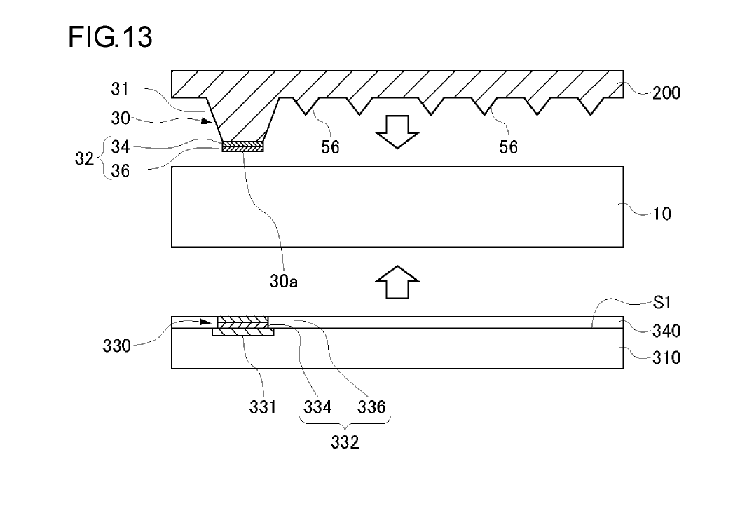

FIG. 13 is a cross-sectional view illustrating a procedure in a method of manufacturing a semiconductor module according to the second embodiment.

As shown in FIG. 13, the copper plate 200, the insulating resin layer 10, and the semiconductor substrate 310 (the semiconductor device 300) are placed between a pair of flat plates (not shown) composing a pressing device. The copper plate 200 is placed on the side of one of the principal surfaces of the insulating resin layer 10, so that the protruding electrode 30 faces the insulating resin layer 10. The semiconductor substrate 310 is placed on the side of the other one of the principal surfaces of the insulating resin layer 10. At this point, the metal layer 32 and the corresponding metal layer 332 are positioned to each other. The flat plates may be made of SiC, for example. By using the pressing device, the copper plate 200 and the semiconductor substrate 310 are pressure-bonded to each other via the insulating resin layer 10. The pressure and temperature at the time of pressing are approximately 5 MPa and 200° C., respectively.

By the pressing, a plastic flow is caused in the insulating resin layer 10, and the protruding electrode 30 penetrates through the insulating resin layer 10. The top end of the top surface 30a of the protruding electrode 30 reaches the surface of the device electrode 330 (or the surface of the Au layer 336), and the two portions are joined to each other. Then, the two portions are pressure-bonded to each other, and the top surface 30a of the protruding electrode 30 is pressed against the device electrode 330, and is deformed. Therefore, the joining portions of the two portions expand from the center region toward the peripheral region. As a result, the copper plate 200, the insulating resin layer 10, and the semiconductor substrate 310 (the semiconductor device 300) are integrated as shown in FIG. 9C, and the protruding electrode 30 and the device electrode 330 are electrically connected.

The insulating resin layer 10 is made of an insulating material that causes a plastic flow when pressure is applied. The side surface shape of the protruding electrode 30 has a diameter that becomes smaller toward the top end. Accordingly, the protruding electrode 30 smoothly penetrates through the insulating resin layer 10. In this embodiment, the copper plate 200 is pressure-bonded to the insulating resin layer 10, so that the insulating resin layer 10 is stacked on the principal surface of the copper plate 200 on the side having the protruding electrode 30 formed thereon.

### Third Embodiment

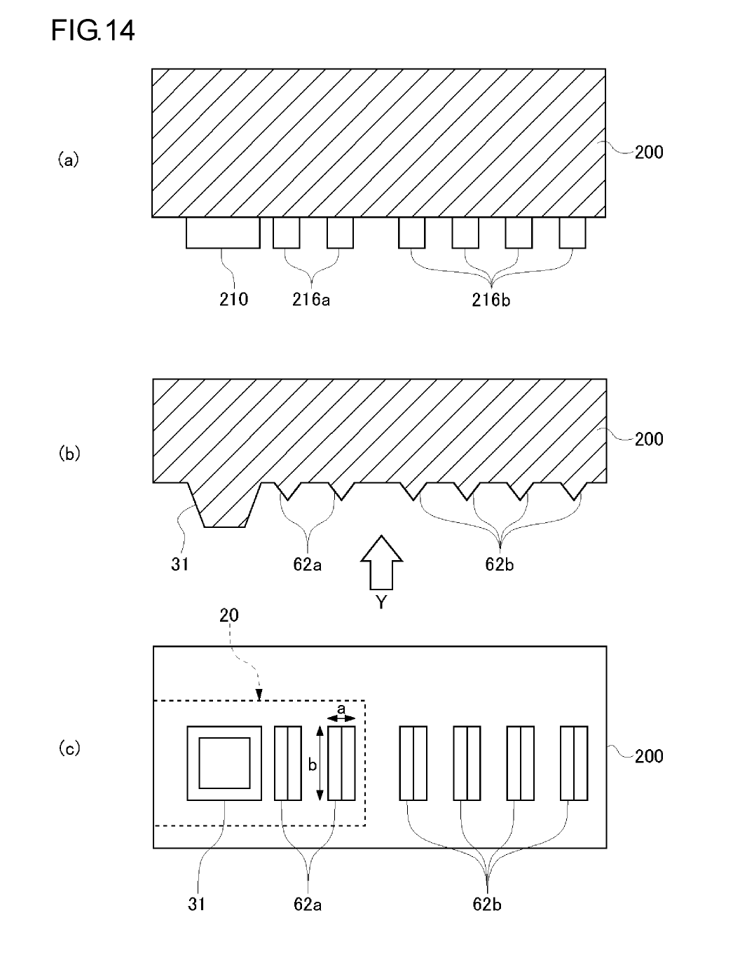

In each of the above described embodiments, the sub bumps 56 for forming the wiring-layer-side convex portions 52 and the resin-layer-side convex portions 54 have conical or truncated conical shapes. However, the pattern described below may be formed on the copperplate, to form the wiring-layer-side convex portions and the resin-layer-side convex portions. FIGS. 14A through 14C are cross-sectional views illustrating procedures for processing the copper plate according to a third embodiment. The same explanation as that in the above described embodiments will not be repeated below.

The copperplate 200 is prepared as a metal plate having a greater thickness at least than the sum of the height of the protruding portion 31 of the protruding electrode 30 and the thickness of the wiring layer 20, as in the first embodiment.

As shown in FIG. 14A, a resist 210 is selectively formed on one of the principal surfaces of the copper plate 200 by a photolithography technique, in accordance with a pattern corresponding to the region in which the protruding electrode 30 is to be formed. At this point, resists 216a and 216b are also selectively formed in accordance with a pattern corresponding to the regions in which later described rectangular sub bumps are to be formed. Specifically, a resist film of a predetermined film thickness is bonded to the copper plate 200 with a laminator device, and exposure is performed with the use of a photomask having a pattern of the protruding electrode 30 and sub bumps 62, followed by development. In this manner, the resists 210, 216a, and 216b are selectively formed on the copper plate 200. The resists 216a correspond to sub bumps 62a forming wiring-layer-side convex portions 64 (described later) among the sub bumps 62, and the resists 216b correspond to the sub bumps 62b contributing to the formation of resin-layer-side convex portions 66 (described later) among the sub bumps 62. The resists 216a and 216b are designed to have shapes and sizes in accordance with desired shapes and sizes of the wiring-layer-side convex portions 64 and the resin-layer-side convex portions 66. Also, the resists 216a may have different sizes and shapes from those of the resists 216b.

As shown in FIG. 14B, with the resist 210 and the resists 216a and 216b (hereinafter referred to as the “resists 216”, where appropriate) serving as masks, a wet etching process using a chemical solution such as aqueous ferric chloride is performed, to form the protruding portion 31 that protrudes from the surface of the copper plate 200 and has a truncated cone pattern, and the sub bumps 62a and 62b (hereinafter referred to as the “sub bumps 62”, where appropriate) that have a pattern of triangular poles. At this point, the protruding portion 31 is designed to have a tapered side surface portion with a diameter (size) becoming smaller toward the top end portion. After the protruding portion 31 and the sub bumps 62 are formed, the resists 210 and 216 are removed with a release agent.

FIG. 14C is a bottom view of the copper plate 200 viewed from the direction of the arrow Y shown in FIG. 14B. The region surrounded by a dotted line in FIG. 14C is the region that is to be the wiring layer 20 in the end through the procedures described in the first embodiment. The sub bumps 62a according to this embodiment are designed so that a length b in a direction perpendicular to the longitudinal direction of the wiring layer 20 is greater than a length a in a direction parallel to the longitudinal direction of the wiring layer 20. In other words, the sub bumps 62a are triangular poles each having a longitudinal direction intersecting with the longitudinal direction of the wiring layer 20.

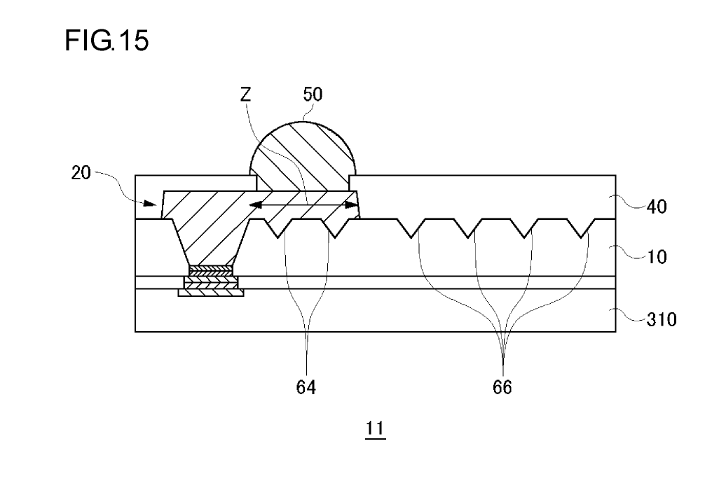

FIG. 15 is a cross-sectional view of a semiconductor module 11 having the wiring-layer-side convex portions 64 and the resin-layer-side convex portions 66 formed therein by using the sub bumps 62 in the same manner as in the first embodiment. In the semiconductor module 11 shown in FIG. 15, when the wiring layer expands and contracts due to thermal expansion, the displacement in the longitudinal direction Z of the wiring layer 20 tends to become relatively larger. The wiring-layer-side convex portions 64 formed in the boundary between the insulating resin layer 10 and the wiring layer 20 each have a longitudinal direction perpendicular to the longitudinal direction Z of the wiring layer 20. Accordingly, at the time of such expansion and contraction, the wiring layer 20 is not easily displaced with respect to the insulating resin layer 10. As a result, the adhesion between the insulating resin layer 10 and the wiring layer 20 at the time of heating or at a high temperature can be improved.

### Fourth Embodiment

Next, a mobile device including the semiconductor module 1 according to each of the above described embodiments is described. Although a cell phone will be described as an example of the mobile device, the mobile device may be an electronic apparatus such as a personal digital assistant (PDA), a digital video camera (DVC), or a digital still camera (DSC).

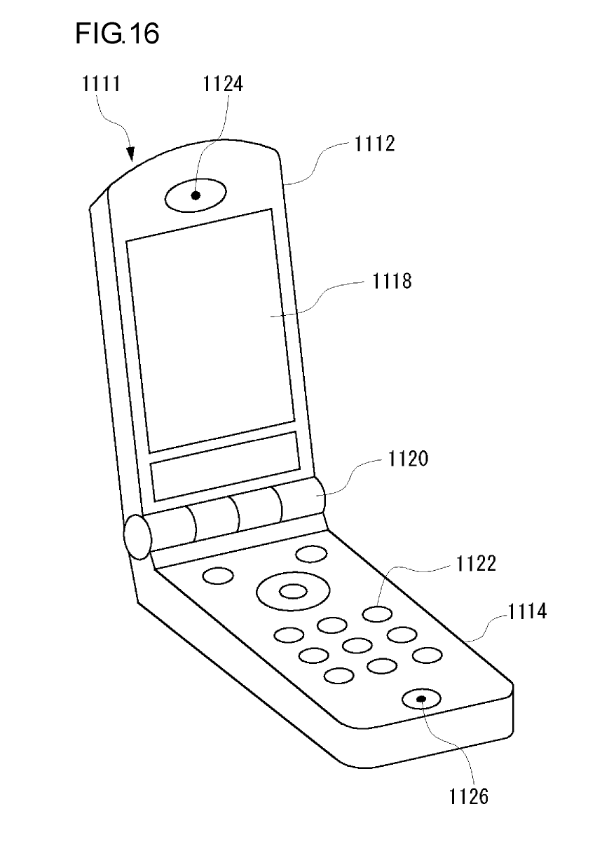

FIG. 16 is a diagram showing the structure of the cell phone according to a fourth embodiment. The cell phone 1111 has a first housing 1112 and a second housing 1114 connected by a movable portion 1120. The first housing 1112 and the second housing 1114 can rotate about the movable portion 1120. A display unit 1118 that displays information such as characters and images, and a speaker unit 1124 are provided on the first housing 1112. An operation unit 1122 such as operation buttons, and a microphone unit 1126 are provided on the second housing 1114. The semiconductor module 1 according to the first embodiment is provided inside the cell phone 1111.

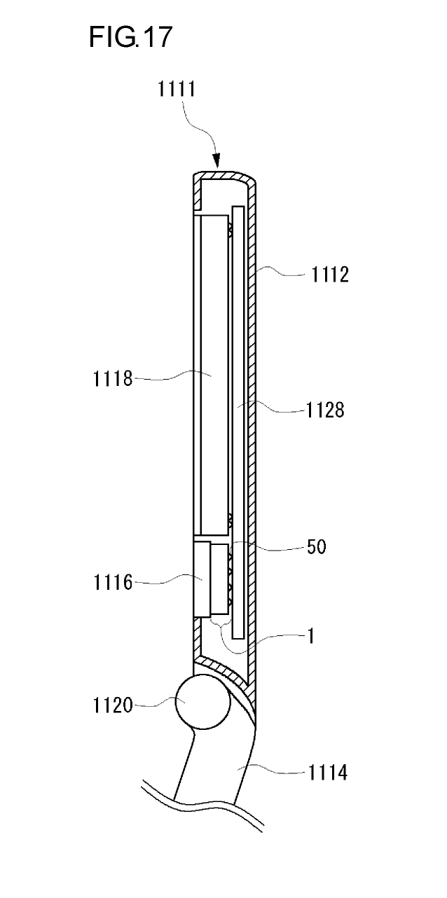

FIG. 17 is a partial cross-sectional view (a cross-sectional view of the first housing 1112) of the cell phone shown in FIG. 16. The semiconductor module 1 according to each of the above described embodiments is mounted on a printed circuit board 1128 via the solder balls 50, and is electrically connected to the display unit 1118 and the like via the printed circuit board 1128. A radiation board 1116 such as a metal substrate is provided on the side of the back surface (the surface on the opposite side from the solder balls 50) of the semiconductor module 1, so that heat generated from the semiconductor module 1 will not stay within the first housing 1112 and can be efficiently released to the outside of the first housing 1112.

In the semiconductor module according to each of the embodiments of the present disclosure, the adhesion between layers such as the wiring layer and the insulating resin layer in the device mounting board 100 is improved. Accordingly, the connection reliability between the semiconductor device 300 and the printed circuit board 1128 via the device mounting board 100 can be increased. Thus, the operation reliability can be increased in the mobile device including the semiconductor module 1 according to this embodiment.

The present disclosure is not limited to the above described embodiments, and various modifications such as design changes can be made based on the knowledge of those skilled in the art. Embodiments having such modifications made thereto are included in the scope of the present disclosure.

What is claimed is:

1. A device mounting board comprising:
a first insulating resin layer;
a wiring layer formed on one of principal surfaces of the first insulating resin layer;
a second insulating resin layer covering the first insulating resin layer and the wiring layer;
a protruding electrode electrically connected to the wiring layer, the protruding electrode protruding from the wiring layer toward the first insulating resin layer and penetrating through the first insulating resin layer;
a wiring-layer-side convex portion protruding from the wiring layer toward the first insulating resin layer and having a top end thereof located inside the first insulating resin layer; and
a resin-layer-side convex portion protruding from the second insulating resin layer toward the first insulating resin layer and having a top end thereof located inside the first insulating resin layer.

2. The device mounting board according to claim 1, wherein
the wiring-layer-side convex portion has a maximum height Rmax of 0.5 μm to 3.0 μm in surface roughness of a side surface thereof.

3. The device mounting board according to claim 1, wherein
the wiring-layer-side convex portion has a pole-like shape having a longitudinal direction intersecting with a longitudinal direction of the wiring layer.

4. The device mounting board according to claim 1, wherein
the wiring-layer-side convex portion has one of a conical shape, a quadrangular pyramid shape, and a triangular pyramid shape.

5. The device mounting board according to claim 1, wherein
the wiring-layer-side convex portion has an inclined surface gradient increasing toward a top end thereof.

6. The device mounting board according to claim 1, wherein
the wiring-layer-side convex portion has a height of 5 μm to 25 μm from a bottom portion of a surface of the wiring layer on a side facing the first insulating resin layer.

7. The device mounting board according to claim 1, wherein
the wiring-layer-side convex portion includes a plurality of protrusions arranged in a predetermined pattern.

8. The device mounting board according to claim 7, wherein
the protrusions have shapes similar to one another.

9. The device mounting board according to claim 1, wherein
the resin-layer-side convex portion has one of a conical shape, a quadrangular pyramid shape, and a triangular pyramid shape.

10. The device mounting board according to claim 1, wherein
the resin-layer-side convex portion has an inclined surface gradient increasing toward a top end thereof.

11. The device mounting board according to claim 1, wherein
the resin-layer-side convex portion has a height of 5 μm to 25 μm from a bottom portion of a surface of the second insulating resin layer on a side facing the first insulating resin layer.

12. The device mounting board according to claim 1, wherein
the resin-layer-side convex portion includes a plurality of protrusions arranged in a predetermined pattern.

13. The device mounting board according to claim 12, wherein
the protrusions have shapes similar to one another.

14. A semiconductor module comprising:
the device mounting board according to claim 1; and
a semiconductor device including a device electrode joined to the protruding electrode of the device mounting board.

15. A mobile device comprising the semiconductor module according to claim 14.

16. A method of manufacturing a device mounting board having an insulating resin layer and a wiring layer stacked therein,
the method comprising:
forming a main bump for a protruding electrode on one of principal surfaces of a metal plate for a wiring layer, and a plurality of sub bumps, the sub bumps being different from the main bump;
joining the one of the principal surfaces of the metal plate and a first insulating resin layer to each other, with top ends of the sub bumps being located inside the first insulating resin layer;
removing a region from the metal plate, part of the sub bumps being formed in the region; and
stacking a second insulating resin layer to cover the first insulating resin layer having concave portions, after the sub bumps are partially removed in the removing.

17. The method according to claim 16, wherein
in the forming the main bump and the sub bumps, a mask for forming the main bump and a mask for forming the sub bumps are made to have different shapes from each other.
